(19) United States
(12) Patent Application Publication
(10) Pub. No.: US 2010/0240170 A1
(43) Pub. Date: Sep. 23, 2010

(54) METHOD OF FABRICATING SOLAR CELL

(75) Inventor: Wen-Ching Sun, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/508,563

(22) Filed: Jul. 24, 2009

(30) Foreign Application Priority Data
Mar. 19, 2009 (TW) 98108931

(51) Int. Cl. H01L 31/0232

(52) U.S. Cl. 438/72; 257/E31.127

(57) ABSTRACT

A method of fabricating a solar cell is provided. A dopant material layer is deposited on a front surface of a semiconductor substrate and an over-depositing dopant layer is also formed on a back surface of the semiconductor substrate, wherein dopants of the dopant material layer diffuse into the front surface of the semiconductor substrate to form a doping layer and dopants of the over-depositing dopant layer diffuse into the back surface of the semiconductor substrate to form a doping residual layer during said depositing process. The dopant material layer and the over-depositing dopant layer are removed. An anti-reflective layer is formed on the doping layer. After the doping residual layer on the semiconductor substrate is removed to expose the back surface of the semiconductor substrate, a passivation layer is formed on the exposed back surface of the semiconductor substrate. Then, a first electrode and a second electrode are formed.

### CROSS-REFERENCE TO RELATED APPLICATION

This application claims the priority benefit of Taiwan application serial no. 98108931, filed on Mar. 19, 2009. The entirety of the above-mentioned patent application is hereby incorporated by reference herein and made a part of this specification.

### BACKGROUND OF THE INVENTION

1. Field of the Invention

The present invention relates to a method of fabricating a solar cell. More particularly, the present invention relates to a method of fabricating a solar cell capable of improving photoelectric conversion efficiency.

2. Description of Related Art

As the petrochemical energy source encounters the pollution and energy shortage problems, the solar energy attracts most of the attentions. Recently, it becomes a quite important research issue to directly convert a solar cell into electric energy. Solar cell is a very promising clean energy source which can generate electricity directly from sunlight, and carbon dioxide, nitride gas or pernicious gases are not generated during generating electric energy, such that the environment is not polluted.

Silicon-based solar cell is a common solar cell in the industry. The working principle of the silicon-base solar cell is that some impurities are added into a semiconductor material (silicon) with high purity, such that the semiconductor material has different features, so as to form a p-type semiconductor and an n-type semiconductor, and to joint the p-type and n-type semiconductors, thereby forming a p-n junction. The p-n junction is formed by positive donor ions and negative acceptor ions, and a built-in potential exists in a region where the positive and negative ions are located. The built-in potential may drive away movable carriers in the region, so that the region is called a depletion region. When the sunlight is irradiated onto a semiconductor with a p-n structure, the energy provided by photons excites electrons in the semiconductor, so as to generate electron-hole pairs. The electrons and holes are both affected by the built-in potential, the holes move towards a direction of the electric field, whereas the electrons move towards an opposite direction. If the solar cell is connected to a load through a wire to form a loop, the current flows through the load, which is the principle for the solar cell to generate electricity.

A backside point contact process is usually performed in the formation of the silicon-based solar cell, which forming a passivation layer on the backside of the solar cell so as to cause back surface field (BSF) effect. Thereby, the carriers collected in the solar cell are increased and the photons not absorbed can be recovered so as to improve the photoelectric conversion efficiency. However, conventionally when forming an n-type layer (n+ layer) on the front surface of the p-type semiconductor substrate with a thermal diffusion process, an n+ layer is also formed on the back surface of the p-type semiconductor substrate. The n+ layer formed on the back surface of the p-type semiconductor substrate decreases BSF effect of the backside point contact electrode. In addition, the sheet-resistance of the back surface of the p-type semiconductor substrate is not uniform because of the formation of the n+ layer thereon, such that the photoelectric conversion efficiency of the solar cell is not good.

### SUMMARY OF THE INVENTION

Accordingly, the present invention is directed to a method of fabricating a solar cell capable of improving photoelectric conversion efficiency.

The present invention provides to a method of fabricating a solar cell. A semiconductor substrate having a front surface and a back surface is provided. A dopant material layer is deposited on the front surface of the semiconductor substrate, and an over-depositing dopant layer is also formed on the back surface of the semiconductor substrate. In particular, dopants of the dopant material layer diffuse into the front surface of the semiconductor substrate to form a doping layer, and dopants of the over-depositing dopant layer diffuse into the back surface of the semiconductor substrate to form a doping residual layer during depositing the dopant material layer. Next, the dopant material layer and the over-depositing dopant layer are removed. After that, an anti-reflective layer is formed on the doping layer on the semiconductor substrate. After the doping residual layer on the semiconductor substrate is removed to expose the back surface of the semiconductor substrate, a passivation layer is formed on the exposed back surface of the semiconductor substrate. Then, a first electrode is formed on the anti-reflective layer and a second electrode is formed on the passivation layer.

In light of the foregoing, the doping residual layer on the back surface of the semiconductor is removed before forming the passivation layer on the back surface of the semiconductor. Thereby, it is benefit for the second electrode to generate BSF effect, and the sheet-resistance of the back surface of the semiconductor is uniform such that the photoelectric conversion efficiency of the solar cell is improved.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a diagram showing a solar cell according to an embodiment of the invention.

FIG. 2A to FIG. 2E are cross-sectional views of a method of fabricating a solar cell according to an embodiment of the invention.

### DESCRIPTION OF EMBODIMENTS

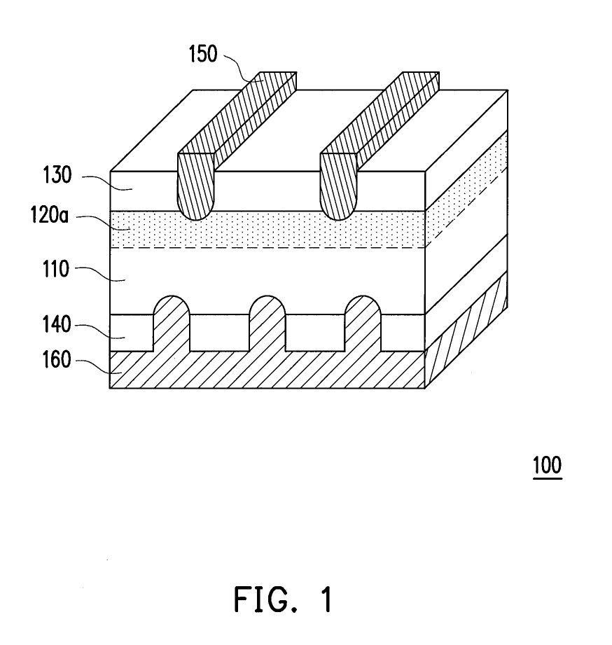

FIG. 1 is a diagram showing a solar cell according to an embodiment of the invention. Referring to FIG. 1, the solar cell 100 comprises a semiconductor substrate 110, a doping layer 120a, an anti-reflective layer 130, a passivation layer 140, a first electrode 150 and a second electrode 160. The method of fabricating the solar cell 100 is described as following.

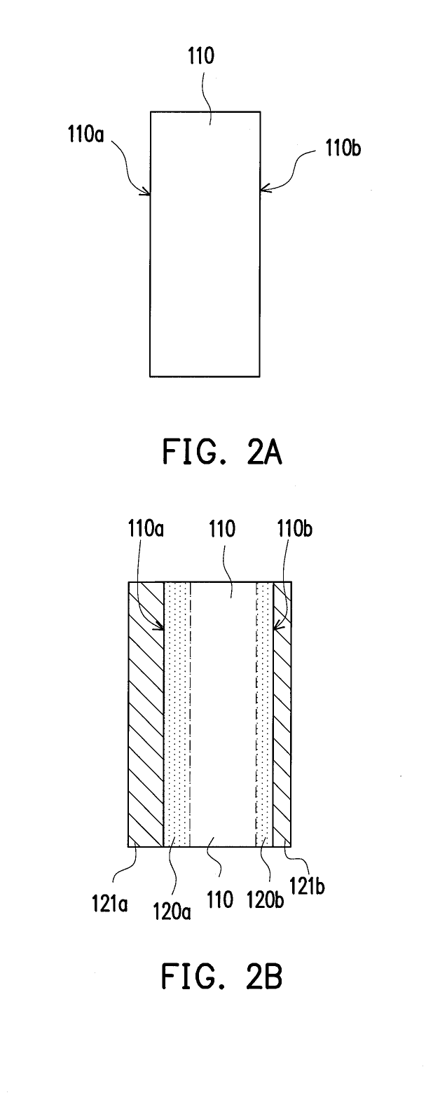

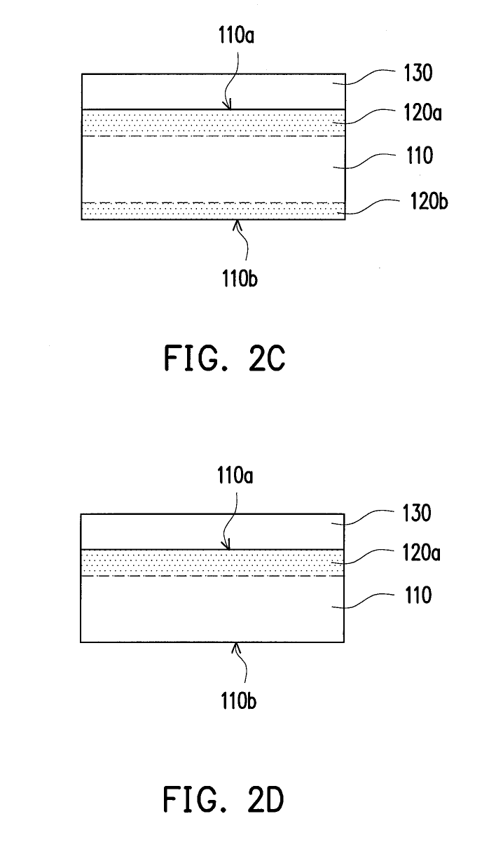

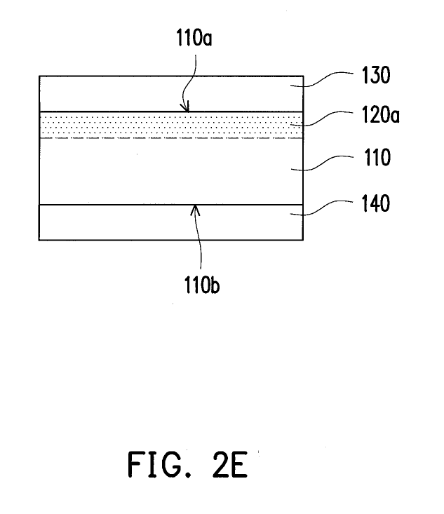

FIG. 2A to FIG. 2E are cross-sectional views of a method of fabricating a solar cell according to an embodiment of the invention. Referring to FIG. 2A, a semiconductor substrate 110 having a front surface 110a and a back surface 110b is provided. In the embodiment, the semiconductor substrate 110 is a silicon based substrate doped with an element of IIIA group, such as boron (B), gallium (Ga) or indium (In), so as to form a p-type semiconductor substrate.

Next, a dopant diffusion process to the semiconductor substrate 110 is performed. In the embodiment, the dopant diffusion process to the semiconductor substrate 110 is performed by disposing the semiconductor substrate 110 in a form of standing inside a depositing chamber, and then depositing a dopant material layer on the surfaces of the semiconductor substrate 110, wherein dopants of the dopant material layer diffuse into the semiconductor substrate 110 through the thermal effect of the depositing process.

In details, as shown in FIG. 2B, after the semiconductor substrate 110 is disposed in the depositing chamber, a depositing process is performed, so as to form a dopant material layer 121 a on the front surface 110a of the semiconductor substrate 110. The dopant material layer 121 a is a material layer comprising n-type dopants therein, and it can be POCl₃, for example. It is noted that, when depositing the dopant material layer 121a on the front surface 110a of the semiconductor substrate 110, the dopant material is also over-deposited on the back surface 110b of the semiconductor substrate 110 to form an over-depositing dopant layer 121b.

In particular, when performing said depositing process, dopants of the dopant material layer 121a diffuse into the front surface 110a of the semiconductor substrate 110 because of the high temperature of the depositing chamber, so as to form a doping layer 120a. In the embodiment, the doping layer 120a is an n-type (n+) doping layer, and thus a p-n junction is formed between the doping layer 120 and the semiconductor substrate 110. However, during said depositing process, dopants of the over-depositing dopant layer 121b also diffuse into the back surface 110b of the semiconductor substrate 110 to form a doping residual layer 120b. The doping residual layer 120b is an n+ residual layer having n-type dopants (such as phosphorous ions) therein.

After the dopant diffusion process is performed, the dopant material layer 121a and the over-depositing dopant layer 121b on the semiconductor substrate 110 are removed, as shown in FIG. 2C. Next, an anti-reflective layer 130 is formed on the doping layer 120a on the semiconductor substrate 110. The anti-reflective layer 130 can be formed by plasma enhanced chemical vapor deposition (PECVD), for example, and has a material of silicon oxide, silicon nitride, aluminum oxide or carbon oxide, for example. The anti-reflective layer 130 in the solar cell not only decreases the sunlight reflection and increases the absorption of the sunlight, but also has a function of passivation so as to reduce the recombination loss of the electron-hole pairs on the surface of the semiconductor substrate 110 in the solar cell.

However, in the meanwhile, the non-uniform doping residual layer 120b is still on the back surface 110b of the semiconductor substrate 110.

Referring to FIG. 2D, the doping residual layer 120b on the back surface 100b of semiconductor substrate 110 is removed to expose the back surface 10b of the semiconductor substrate 110. In the embodiment, the doping residual layer 120b is removed by performing a plasma immersion ion implantation (PIII) with hydrogen plasma. The doping residual layer 120b can be removed fast and uniformly by this removing method, and the back surface 110b of the semiconductor substrate 110 is also implanted with hydrogen ions at the same time. The plasma treatment comprises applying a negative pulse voltage between −500˜−5 kV, the pulse duration of the negative pulse voltage is from 1 μsec to 20 μsec, the pulse frequency of the negative pulse voltage is from 100 Hz to 20 kHz, and the period of the plasma treatment is between 1 to 10 min. In a preferred embodiment, the plasma treatment with hydrogen plasma comprises applying a negative pulse voltage of −4 kV, the pulse duration of the negative pulse voltage is 1 μsec, the pulse frequency of the negative pulse voltage is 300 Hz, and the period of the plasma treatment is 10 min. The implanting depth of hydrogen ions is controlled through adjusting the recipes of the plasma treatment. It should be noted that the implanted hydrogen ions diff-use into the semiconductor substrate 110 during the subsequently thermal processes to generate bulk passivation effect, such that the recombination loss of the electron-hole pairs on the lattice defect can be reduced.

In the above-mentioned embodiment, the plasma treatment with hydrogen plasma is used to remove the doping residual layer 120b on the semiconductor substrate 110, but the present invention does not limit thereto. According to another embodiment, the plasma treatment with argon plasma can also be used to remove the doping residual layer 120b on the semiconductor substrate 110. In addition to the plasma treatment, a wet etching process can also be used to remove the doping residual layer 120b on the semiconductor substrate 110. The wet etching process comprises using an etchant having hydrofluoric acid, for example.

Referring to FIG. 2E, after removing the doping residual layer 120b on the back surface 110b of the semiconductor substrate 110 to expose the back surface 110b of the semiconductor substrate 110, a passivation layer 140 is formed on the exposed back surface 110b of the semiconductor substrate 110. The passivation layer 140 comprises silicon oxide, silicon nitride, aluminum oxide or carbon oxide.

Thereafter, a first electrode 150 and a second electrode 160 are respectively formed on the anti-reflection layer 130 and the passivation layer 140, as shown in FIG. 1. The first electrode 150 and the second electrode 160 respectively comprise a metal material or a transparent conductive oxide. The first electrode 150 and the second electrode 160 can be formed by the well known printing process, evaporation process or sputtering process.

It is noted that the solar cell of the embodiments is formed by the backside point contact process, and thus the second electrode 160 generates back surface field (BSF) effect. Thereby, the carriers collected in the solar cell are increased and the photons not absorbed can be recovered so as to improve photoelectric conversion efficiency. However, if the doping residual layer 120b (as shown in FIG. 2D) is not removed before the passivation layer 140 is formed, the BSF effect is reduced and the photoelectric conversion efficiency is deteriorated. An Example and a Comparison Example are described in the following paragraphs to explain the solar cell fabricated by the method of the present invention has a better performance than the solar cell formed by the conventional backside point contact process.

### EXAMPLE

The method of fabricating the solar cell of the Example comprises removing the doping residual layer on the back surface of the semiconductor substrate with hydrogen treatment before the passivation layer is formed on the back surface of the semiconductor substrate. The detailed process steps are as shown in FIG. 2A˜FIG. 2E and described in the related paragraphs.

### Comparison Example

The process steps and the materials for fabricating the solar cell in the Comparison Example are similar to the above Example, and the difference therebetween is that the back surface of the semiconductor substrate is not treated with any process before forming the passivation layer on the back surface of the semiconductor substrate, and thus a doping residual layer is remained on the back surface of the semiconductor substrate.

Electrical properties of the solar cells of the Example and the Comparison Example are measured under the same measuring condition and shown in Table 1.

TABLE 1

| | size of | open- | short-circuit | | photoelectric |
|---|---|---|---|---|---|
| | solar | circuit | current | filling | conversion |
| | cell | voltage | density | factor | efficiency |
| | (mm²) | (V) | (mA/cm²) | (%) | (%) |
| Comparison | 100 * 100 | 0.613 | 35.78 | 73.33 | 16.08 |
| Example | | | | | |
| Example | 100 * 100 | 0.622 | 36.122 | 74.37 | 16.71 |

As Table 1 shown, the open-circuit voltage of the solar cell in Example is 0.622V, while the open-circuit voltage of the solar cell in Comparison Example is 0.613V; and the short-circuit current density of the solar cell in Example is raised to 36.122 mA/cm² from 35.78 mA/cm² because of the passivation effect. In addition, the filling factor and the photoelectric conversion efficiency of the solar cell in Example are better than that of the solar cell in Comparison Example.

In the method of fabricating the solar cell of the present invention, the doping residual layer on the back surface of the semiconductor substrate is removed with plasma treatment or etching process before the passivation layer is formed. It is benefit for the solar cell to generate better BSF effect. In addition, the solar cell formed by the method comprising removing the doping residual layer on the back surface of the semiconductor substrate has uniform sheet resistance, and thus the photoelectric conversion efficiency of the solar cell is increased. In particular, if the doping residual layer is removed with hydrogen plasma, hydrogen ions are also implanted into the back surface of the semiconductor substrate at the same time. That is, the removal of the doping residual layer and the bulk passoivation effect are achieved at the same time, and thus the fabricating time and cost are reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a solar cell, comprising:
providing a semiconductor substrate having a front surface and a back surface;
depositing a dopant material layer on the front surface of the semiconductor substrate, and an over-depositing dopant layer is also formed on the back surface of the semiconductor substrate, wherein dopants of the dopant material layer diffuse into the front surface of the semiconductor substrate to form a doping layer and dopants of the over-depositing dopant layer diffuse into the back surface of the semiconductor substrate to form a doping residual layer during depositing the dopant material layer;
removing the dopant material layer and the over-depositing dopant layer;
forming an anti-reflective layer on the doping layer on the semiconductor substrate;
removing the doping residual layer on the semiconductor substrate to expose the back surface of the semiconductor substrate;
forming a passivation layer on the exposed back surface of the semiconductor substrate; and
forming a first electrode on the anti-reflective layer and forming a second electrode on the passivation layer.

2. The method as claimed in claim 1, wherein the step of removing the doping residual layer on the semiconductor substrate comprises performing a plasma treatment.

3. The method as claimed in claim 2, wherein the plasma treatment comprises using hydrogen plasma.

4. The method as claimed in claim 3, wherein the plasma treatment comprises applying a negative pulse voltage between −500˜−5 kV, the pulse duration of the negative pulse voltage is from 1 μsec to 20 μsec, the pulse frequency of the negative pulse voltage is from 100 Hz to 20 kHz, and the period of the plasma treatment is between 1 to 10 min.

5. The method as claimed in claim 2, wherein the plasma treatment comprises using argon plasma.

6. The method as claimed in claim 1, wherein the step of removing the doping residual layer on the semiconductor substrate comprises performing a wet etching process.

7. The method as claimed in claim 6, wherein the wet etching process comprises using an etchant having hydrofluoric acid.

8. The method as claimed in claim 1, wherein the doping layer is an n-type doping layer.

9. The method as claimed in claim 1, wherein the dopant material layer comprises POCl₃.

10. The method as claimed in claim 1, wherein the semiconductor substrate is a p-type semiconductor substrate.

11. The method as claimed in claim 1, wherein the doping residual layer is an n-type doping residual layer.

12. The method as claimed in claim 1, wherein the anti-reflective layer and the passivation layer respectively comprise silicon oxide, silicon nitride, aluminum oxide or carbon oxide.

13. The method as claimed in claim 1, wherein the first electrode and the second electrode respectively comprise a metal material or a transparent conductive oxide.
